(19) United States
(12) Patent Application Publication
(10) Pub. No.: US 2026/0223579 A1
(43) Pub. Date: Jul. 30, 2026

(54) DISPLAY PANEL, MANUFACTURING METHOD FOR DISPLAY PANEL, AND DISPLAY DEVICE

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Ying CUI, Beijing (CN); Juanjuan YOU, Beijing (CN); Cheng XU, Beijing (CN); Dandan ZHOU, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 19/145,947

(22) PCT Filed: Jun. 21, 2024
(86) PCT No.: PCT/CN2024/100728

§ 371 Date: Jul. 7, 2025

(30) Foreign Application Priority Data
Jul. 28, 2023 (CN) 202310946708.5

(51) Int. Cl. H10K 59/80; H10K 59/12; H10K 59/121; H10K 59/122; H10K 59/123

(52) U.S. Cl. CPC H10K 59/879; H10K 59/1201; H10K 59/1213; H10K 59/122; H10K 59/123

(57) ABSTRACT

Provided is a display panel. The display panel includes a base substrate, a circuit structural layer, a first structural layer, a second structural layer, and light-emitting units that are stacked sequentially. The first structural layer includes a plurality of light extraction structures arranged in an array; and each of the light-emitting units includes a first electrode and an electroluminescent layer stacked on the second structural layer in a direction away from the first structural layer, the first electrode being electrically connected to the circuit structural layer, and a surface of the second structural layer close to the first structural layer is in conformity with a surface of the first structural layer away from the base substrate; wherein a refractive index of the second structural layer is greater than a refractive index of the first structural layer and less than or equal to a refractive index of the first electrode.

### CROSS-REFERENCE TO RELATED APPLICATIONS

This application is a U.S. national stage of international application No. PCT/CN2024/100728, filed on Jun. 21, 2024, and claims priority to Chinese Patent Application No. 202310946708.5, filed on Jul. 28, 2023, and entitled “DISPLAY PANEL, MANUFACTURING METHOD FOR DISPLAY PANEL, AND DISPLAY DEVICE”, the contents of each are incorporated herein by reference in its entirety.

### TECHNICAL FIELD

The present disclosure relates to the field of display technologies, and in particular relates to a display panel, a method for manufacturing a display panel, and a display device.

### BACKGROUND

A display panel is a component capable of displaying images.

### SUMMARY

Some embodiments of the present disclosure provide a display panel, a method for manufacturing a display panel, and a display device.

According to some embodiments of the present disclosure, a display panel is provided. The display panel includes:
a base substrate;
a circuit structural layer disposed on the base substrate;
a first structural layer disposed on a side of the circuit structural layer away from the base substrate, wherein the first structural layer includes multiple light extraction structures arranged in an array, and the multiple light extraction structures include at least one of protrusion structures and recess structures;
a second structural layer disposed on a side of the first structural layer away from the base substrate; and
light-emitting units disposed on the second structural layer, wherein each of the light-emitting units includes a first electrode and an electroluminescent layer stacked on the second structural layer in a direction away from the first structural layer, the first electrode being electrically connected to the circuit structural layer, and a surface of the second structural layer close to the first structural layer is in conformity with a surface of the first structural layer away from the base substrate;
wherein a refractive index of the second structural layer is greater than a refractive index of the first structural layer and less than or equal to a refractive index of the first electrode.

In some embodiments, the second structural layer includes multiple sub-film layers stacked in a cascade, and a refractive index of any sub-film layer among the multiple sub-film layers is positively correlated with a first distance, the first distance being a distance in a direction perpendicular to the base substrate between the sub-film layer and the first structural layer.

In some embodiments, the multiple sub-film layers include a first sub-film layer adjacent to the first structural layer and a second sub-film layer adjacent to the first electrode, a refractive index of the first sub-film layer being greater than the refractive index of the first structural layer, and a refractive index of the second sub-film layer being less than or equal to the refractive index of the first electrode.

In some embodiments, the multiple sub-film layers further include a third sub-film layer disposed between the first sub-film layer and the second sub-film layer, wherein the refractive index of the first sub-film layer is in a range (1.5, 1.6], a refractive index of the third sub-film layer is in a range (1.6, 1.7], and the refractive index of the second sub-film layer is in a range (1.7, 1.8].

In some embodiments, the plurality of sub-film layers is formed as an integral structure.

In some embodiments, the multiple sub-film layers all include a base layer and particles doped in the base layer, and a concentration of the particles in each of the multiple sub-film layers is positively correlated with the first distance.

In some embodiments, the base layer is made of a polymethyl methacrylate material, a polyimide-based material, or an epoxy resin-based material.

In some embodiments, the particles include at least one of zirconium oxide or titanium oxide.

In some embodiments, a distance between centers of two adjacent light extraction structures among the multiple light extraction structures is ½ of a height difference in the first structural layer, the height difference being a maximum distance between two positions on the first structural layer in a direction perpendicular to the base substrate.

In some embodiments, the height difference ranges from 0.2 microns to 1.5 microns.

In some embodiments, wherein in the direction perpendicular to the base substrate, the height difference in the first structural layer is equal to a minimum distance between a light extraction structure in the first structural layer and the first electrode.

In some embodiments, the display panel further includes a pixel defining layer disposed between the second structural layer and the electroluminescent layer, wherein the pixel defining layer is provided with openings, and the electroluminescent layer covers the openings, an orthographic projection of the pixel defining layer on the base substrate being overlapped with an orthographic projection of the multiple light extraction structures on the base substrate.

In some embodiments, a surface of the first electrode close to the base substrate is in conformity with a surface of the second structural layer close to the first electrode, and the surface of the second structural layer close to the first electrode is flat or the surface of the second structural layer close to the first electrode and a surface of the first structural layer close to the second structural layer are both concave-convex.

In some embodiments, a thickness of the first structural layer is equal to a thickness of the second structural layer.

In some embodiments, the protrusion structures include at least one selected from a group consisting of a convex lens, a triangular protrusion structure, a columnar protrusion structure, and a trapezoidal protrusion structure; and

the recess structures include at least one selected from a group consisting of a concave lens, a triangular recess structure, a columnar recess structure, and a trapezoidal recess structure.

In some embodiments, the electroluminescent layer is a white electroluminescent layer for emitting white light; and

the display panel further includes a color filter layer disposed between the first structural layer and the base substrate, and an orthographic projection of the white electroluminescent layer on the base substrate is overlapped with an orthographic projection of the color filter layer on the base substrate.

In some embodiments, the circuit structural layer includes a thin film transistor, and the thin film transistor includes a first pole, a second pole, and a gate, the gate being configured to control on/off of the first pole and the second pole, and the first pole being connected to the first electrode of the light-emitting unit.

According to some embodiments of the present disclosure, a method for manufacturing a display panel is provided. The method includes the following steps.

A base substrate is acquired.

A circuit structural layer is formed on the base substrate.

A first structural layer is formed on a side of the circuit structural layer away from the base substrate, wherein the first structural layer includes multiple light extraction structures arranged in an array on a side away from the base substrate, and the multiple light extraction structures include at least one of a protrusion structure and a recess structure.

A second structural layer is formed on a side of the first structural layer away from the base substrate.

Light-emitting units are formed on the second structural layer, wherein each of the light-emitting units includes a first electrode and an electroluminescent layer stacked on the second structural layer in a direction away from the first structural layer, the first electrode being electrically connected to the circuit structural layer, and a surface of the second structural layer close to the first structural layer is in conformity with a surface of the first structural layer on a side away from the base substrate, a refractive index of the second structural layer being greater than a refractive index of the first structural layer and less than or equal to a refractive index of the first electrode.

In some embodiments, the second structural layer includes multiple sub-film layers stacked in a cascade, and forming the second structural layer on the side of the first structural layer away from the base substrate includes:
forming the multiple sub-film layers stacked on the side of the first structural layer away from the base substrate, wherein a refractive index of any sub-film layer among the multiple sub-film layers is positively correlated with a first distance, the first distance being a distance in a direction perpendicular to the base substrate between the sub-film layer and the first structural layer.

According to some embodiments of the present disclosure, a display device is provided. The display device includes a housing and a display panel according to any one of the above embodiments, wherein the display panel is disposed in the housing.

### BRIEF DESCRIPTION OF THE DRAWINGS

To describe technical solutions in the embodiments of the present disclosure more clearly, the following briefly introduces the accompanying drawings required for describing the embodiments. Apparently, the accompanying drawings in the following description illustrate merely some embodiments of the present disclosure, and a person of ordinary skill in the art may still derive other drawings from these accompanying drawings without creative efforts.

FIG. 1 is a schematic structural diagram of a present display panel;

FIG. 2 is a schematic structural diagram of a display panel according to some embodiments of the present disclosure;

FIG. 3 is a cross-sectional structural schematic diagram of the display panel shown in FIG. 2;

FIG. 4 is a schematic structural diagram of another display panel according to some embodiments of the present disclosure;

FIG. 5 is a schematic structural diagram of a top view of a first structural layer in the display panel shown in FIG. 4;

FIG. 6 is a schematic structural diagram of another display panel according to some embodiments of the present disclosure;

FIG. 7 is a schematic structural diagram of another display panel according to some embodiments of the present disclosure;

FIG. 8 is a schematic structural diagram of a top view of another first structural layer in a display panel according to some embodiments of the present disclosure;

FIG. 9 is a schematic structural diagram of a top view of another first structural layer in a display panel according to some embodiments of the present disclosure;

FIG. 10 is a schematic structural diagram of another display panel according to some embodiments of the present disclosure;

FIG. 11 is a schematic structural diagram of another display panel according to some embodiments of the present disclosure;

FIG. 12 is a schematic structural diagram of another display panel according to some embodiments of the present disclosure;

FIG. 13 is a schematic structural diagram of another display panel according to some embodiments of the present disclosure;

FIG. 14 is a schematic structural diagram of another display panel according to some embodiments of the present disclosure;

FIG. 15 is a schematic structural diagram of another display panel according to some embodiments of the present disclosure;

FIG. 16 is a schematic structural diagram of another display panel according to some embodiments of the present disclosure;

FIG. 17 is a flowchart of a method for manufacturing a display panel according to some embodiments of the present disclosure;

FIG. 18 is a flowchart of another method for manufacturing a display panel according to some embodiments of the present disclosure.

Specific embodiments of the present disclosure have been shown by means of the above-described accompanying drawings, which will be described in greater detail later. These accompanying drawings and written descriptions are not intended to limit the scope of the present disclosure in any way, but rather to explain the concepts of the present disclosure for those skilled in the art by reference to specific embodiments.

### DETAILED DESCRIPTION

For clearer descriptions of the objects, technical solutions, and advantages of the present disclosure, the embodiments of the present disclosure are further described in detail below with reference to the drawings.

The display panel includes a base substrate and a circuit structure, a structural layer, a first structural layer, an anode, an electroluminescent layer, and a cathode sequentially disposed on the base substrate, wherein the electroluminescent layer can emit light under the driving of the anode and the cathode. The light passes through the anode, the first structural layer, and the base substrate sequentially and then exists the display panel. The first structural layer includes multiple concave and convex structures, which improve the light extraction efficiency of the display panel.

However, the first structural layer may cause the thickness of the electroluminescent layer to be uneven, resulting in a poor display effect of the display panel.

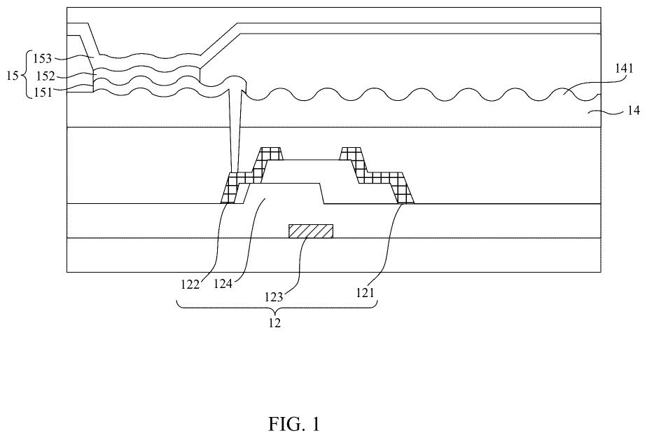

FIG. 1 is a schematic structural diagram of a present display panel. The display panel includes a base substrate 11, a thin film transistor (TFT) 12 disposed on the base substrate 11, a first structural layer 14, and a light-emitting unit 15.

The thin film transistor 12 includes a source 121, a drain 122, a gate 123, and an active layer 124. The first structural layer 14 includes multiple protrusion structures 141 (such as convex lenses). And the light-emitting unit 15 includes an anode 151, an electroluminescent layer 152, and a cathode 152.

Due to the multiple protrusion structures 141 present in the first structural layer 14, the surface of the first structural layer 14 in contact with the anode 151 is uneven (the upper surface of the first structural layer 14 in FIG. 1), and the height difference between the convex point of the protrusion structure 141 and the concave point of the protrusion structure 141 is large, resulting in a poor flatness of the film layers formed on the first structural layer 14. This may lead to fractures, and further give rise to various defects of the pixels, such as uneven brightness and the inability to emit light normally. Exemplarily, the anode 151 formed directly on the first structural layer 14 may break due to the sharpness of the protrusion structures 141, thereby causing the light-emitting unit 15 to be unable to emit light normally. In addition, the thickness of the electroluminescent layer 152 subsequently formed on the anode 151 may vary greatly in different regions. As a result, the brightness of the regions with a thicker thickness may be lower, or the regions with a thicker thickness may not be driven to emit light, which affects the aperture ratio of the display panel, thereby affecting the display effect of the display panel.

Embodiments of the present disclosure provide a display panel, a method for manufacturing a display panel, and a display device, which solve some of the problems in the above-related art.

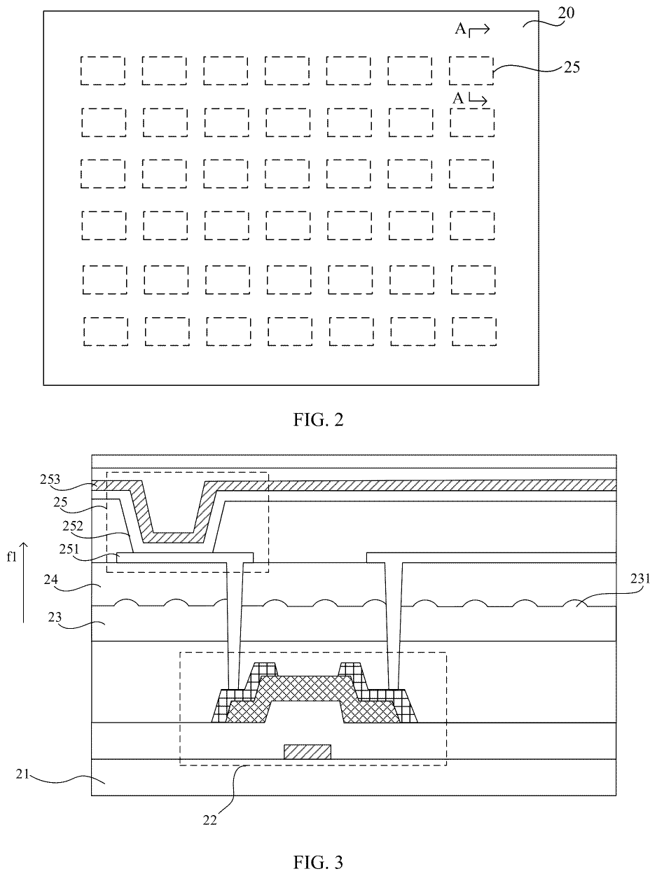

FIG. 2 is a schematic structural diagram of a display panel according to some embodiments of the present disclosure, and FIG. 3 is a cross-sectional structural schematic diagram of the display panel shown in FIG. 2 (FIG. 3 may be a cross-sectional structural schematic diagram of the display panel shown in FIG. 2 at A-A). Referring to FIGS. 2 and 3, the display panel includes: a base substrate 21; a circuit structural layer 22 disposed on the base substrate 21; a first structural layer 23 disposed on a side of the circuit structural layer 22 away from the base substrate 21, wherein the first structural layer 23 includes multiple light extraction structures 231 arranged in an array, the multiple light extraction structures 231 including at least one of protrusion structures or recess structures; a second structural layer 24 disposed on a side of the first structural layer 23 away from the base substrate 21; light-emitting units 25, wherein each of the light-emitting units 25 includes a first electrode 251 and an electroluminescent layer 252 stacked on the second structural layer 24 in a direction f1 away from the second structural layer 24, the first electrode 251 being electrically connected to the circuit structural layer 22, a surface of the second structural layer 24 close to the first structural layer 23 is in conformity with a surface of the first structural layer 23 away from the base substrate 21. A refractive index of the second structural layer 24 is greater than a refractive index of the first structural layer 23 and is less than or equal to a refractive index of the first electrode 251.

The refractive index of the second structural layer 24 is greater than the refractive index of the first structural layer 23, so that light with a larger exit angle (greater than the critical angle of the interface between the second structural layer 24 and the first structural layer 23) will undergo total internal reflection at the interface between the second structural layer 24 and the first structural layer 23, so as to prevent this part of the light directly exiting the display panel, thereby realizing the light screening, which enables the screening of light with a smaller exit angle than the critical angle and allowing this part of the light to exit the display panel. In addition, that the refractive index of the second structural layer 24 is less than the refractive index of the first electrode 251 also plays a role of screening, resulting in screening the light emitted from the first electrode 251 to the second structural layer 24. And the light is directly emitted from the first electrode 251 into the second structural layer 24 when the refractive index of the second structural layer 24 is equal to the refractive index of the first electrode 251.

In some embodiments of the present application, the display panel is a bottom-emission display panel. That is, light is emitted from the substrate (base substrate) side of the display panel.

In addition, the light-emitting unit 25 also includes a second electrode 253. One of the first electrode 251 and the second electrode 253 is an anode and the other electrode is a cathode. Exemplarily, the first electrode 251 is the anode and the second electrode 253 is the cathode, and the electroluminescent layer 252 emits light under the driving of the first electrode 251 and the second electrode 253.

It should be noted that the “protrusion structure” herein refers to a structure protruding in the direction away from the base substrate, and the “recess structure” herein refers to a structure recessing in the direction toward the base substrate.

In summary, according to the display panel provided by the embodiments of the present disclosure, the second structural layer is provided on the first structural layer having the light extraction structure, and the first electrode and the electroluminescent layer in the light-emitting unit are sequentially provided on the second structural layer. Since the refractive index of the second structural layer is greater than that of the first structural layer and is less than or equal to that of the first electrode, the second structural layer guides the light incident on the first electrode out of the first electrode and transmit it through the second structural layer toward the first structural layer, so that the light extraction structure on the first structural layer processes the light to improve the light extraction efficiency, which improves the uniformity of the thickness of the electroluminescent layer without decreasing the light extraction efficiency and solves the problem of poor display effect of the display panel caused by the uneven thickness of the electroluminescent layer in the related art, thereby enhancing the display effect of the display panel.

In the display panel provided by the embodiments of the present disclosure, the first structural layer is a structure for improving the light extraction efficiency of the display panel, such as a microlens structure. The microlens structure is widely used in variety display devices. The “light extraction efficiency” in the embodiments of the present disclosure is related to the amount of light emitted from the display panel among the light emitted by the electroluminescent layer, and the larger the amount of emitted light indicates a higher light extraction efficiency of the surface. When the light extraction efficiency of the display panel is improved, the brightness as well as the display effect of the display panel are also enhanced accordingly.

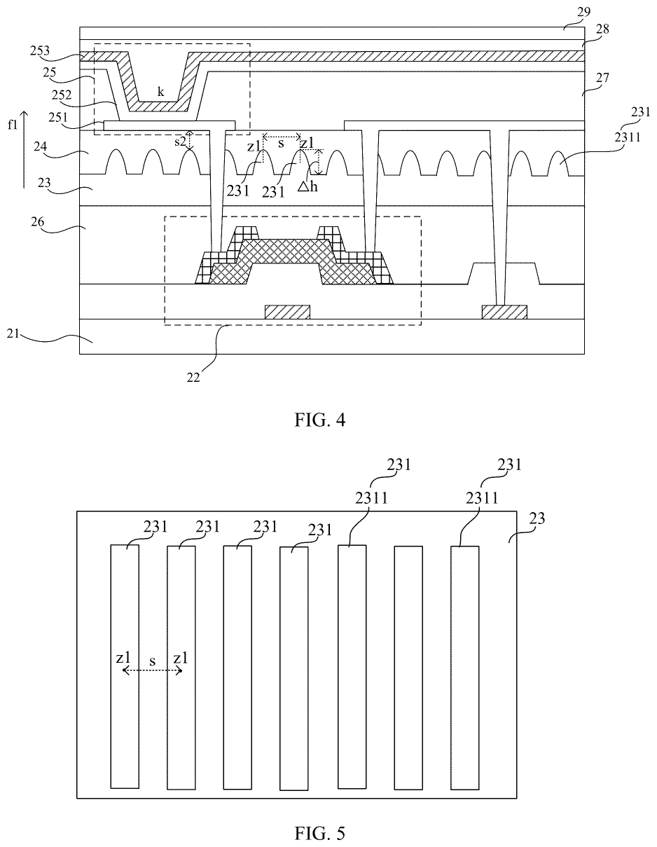

FIG. 4 is a schematic structural diagram of another display panel according to some embodiments of the present disclosure, and FIG. 5 is a schematic structural diagram of a top view of a first structural layer in the display panel shown in FIG. 4, referring to FIG. 4 and FIG. 5, the first structural layer 23 include multiple protrusion structures 2311 in an array. The protrusion structure 2311 may include at least one selected from a group consisting of a convex lens, a triangular protrusion structure, a columnar protrusion structure, and a trapezoidal protrusion structure. FIG. 4 illustrates a structure where the protrusion structure 2311 is a convex lens, but embodiments of the present disclosure do not limit this.

In some embodiments, the distance s between the centers z1 (the center z1 is a geometric center or a gravity center of the light extraction structure 231) of two adjacent light extraction structures 231 in the first structural layer 23 is half of the height difference Δh in the first structural layer 23. The height difference Δh is the maximum distance between two positions on the first structural layer 23 in the direction f1 perpendicular to the base substrate 21. When the first structural layer 23 satisfies such a condition, the influence of the first structural layer 23 on the light extraction efficiency can be enhanced, thereby improving the light extraction efficiency of the display panel. It should be noted that the size ratios between the structures in FIG. 4 are only for illustrative purposes and do not represent the actual size ratios between the structures.

In the first structural layer of the display panel provided by the embodiments of the present disclosure, in the case that the first structural layer 23 merely includes the protrusion structure 2311 (FIG. 4 illustrates such a structure), the maximum distance (the height difference Δh) between two positions on the first structural layer 23 refers to the distance in the direction f1 between the top of the protrusion structure 2311 (the point of the protrusion structure 2311 farthest from the base substrate 21 in the direction f1 perpendicular to the base substrate 21) and the bottom of the protrusion structures 2311 (the point closest to the base substrate 21 in the direction f1 perpendicular to the base substrate 21).

In some embodiments, the surface of the first electrode 251 away from the base substrate 21 (the upper surface of the first electrode 251 in FIG. 4) is in conformity with the surface of the second structural layer 24 close to the first electrode 251 (the upper surface of the second structural layer 24 in FIG. 4). The surface of the second structural layer 24 close to the first electrode 251 is a flat surface (FIG. 4 illustrates such a structure, in which the second structural layer 24 is equivalently reused as a planarization layer, and the flat surface may not be absolutely flat but approximately flat). In this structure, the second structural layer 24 prevents the uneven surface of the first structural layer 23 from affecting the first electrode 251, allowing the first electrode 251 to be formed on the second structural layer 24 with the flat surface. In some other embodiments, the surface of the second structural layer close to the first electrode and the surface of the first structural layer close to the second structural layer are both concave-convex. Due to the second structural layer, the concavity and convexity degree of the first structural layer 23 (which can be determined by the difference between the thickness at the thickest position and the thinnest position) is smaller than that of the first structural layer, thereby reducing the influence of the uneven surface of the first structural layer 23 on the surface of the first electrode 251.

As shown in FIG. 6, FIG. 6 is a schematic structural diagram of another display panel according to some embodiments of the present disclosure. In the case that the first structure layer 23 merely includes the recess structures 2312, the maximum distance (the height difference Δh) between two positions on the first structural layer 23 refers to the distance in the direction f1 between the bottom of the recess structure 2312 (the point of the recess structure 2312 closest to the base substrate 21 in the direction f1 perpendicular to the base substrate 21) and the top of the recess structure 2312 (the point farthest from the base substrate 21 in the direction f1 perpendicular to the base substrate 21).

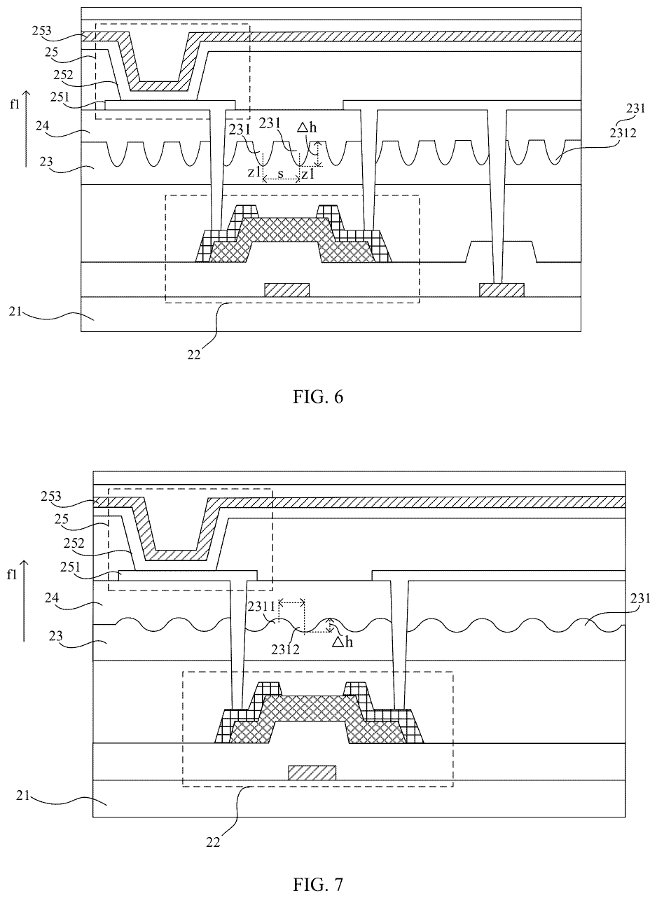

As shown in FIG. 7, FIG. 7 is a schematic structural diagram of another display panel according to some embodiments of the present disclosure. In the case that the first structure layer 23 includes the protrusion structures 2311 and the recess structures 2312, the maximum distance (the height difference Δh) between two positions on the first structural layer 23 is a distance between the top of the protrusion structure 2311 and the bottom of the recess structure 2312 in the direction f1. In the structure, the protrusion structures 2311 and the recess structures 2312 are alternately arranged in the first structural layer 23, with the adjacent light extraction structures 231 of the protrusion structure 2311 being the recess structures 2312.

In addition, referring to FIG. 4, the display panel further includes other structures. For example, the display panel includes a third structural layer 26, a pixel defining layer 27, a forth structural layer 28, and an packaging layer 29. The third structural layer 26 is disposed between the circuit structural layer 22 and the first structural layer 23, since the circuit structural layer 22 has a large step difference in different regions, the third structural layer 26 provides a formation surface for the upper film structure (e.g., the first structural layer 23) to enhance the positive effect of the first structural layer 23 on the light extraction efficiency. The pixel defining layer (PDL) 27 is disposed between the second structural layer 24 and the electroluminescent layer 252. The pixel defining layer 27 has multiple openings k, and the electroluminescent layer 252 covers the openings k. The second electrode 253 covers the electroluminescent layer 252, such that the electroluminescent layer 252 in the openings k is in contact with the first electrode 251 and the second electrode 252. The second electrode 252 and the first electrode 251 then drive the electroluminescent layer 252 disposed in the opening of the pixel defining layer 27 to emit light. The forth structural layer 28 is disposed above the second electrode 253 for providing a formation surface to a subsequent film layer (such as the packaging layer 29). Exemplarily, the forth structural layer 28 structures the step difference caused by the openings k in the pixel defining layer 27. The packaging layer 29 is disposed on a side of the forth structural layer 28 away from the base substrate 21 for packaging the various devices in the display panel to protect them. In some embodiments of the present disclosure, the first electrode 251 is made of transparent conductive material, such as indium tin oxide (ITO), with a refractive index that may be 1.8. The refractive index of the second structural layer 24 may be equal to the refractive index of the first electrode 251.

In the display panel according to some embodiments of the present disclosure, the orthographic projection of the first electrode 251 on the base substrate 21 may overlap with the orthographic projection of the light extraction structure 231 on the base substrate 21, so as to enhance the light extraction efficiency for light emitted by the electroluminescent layer 252 in the downward direction. In addition, the orthographic projection of the pixel defining layer 27 on the base substrate 21 may overlap with the orthographic projection of the light extraction structure 231 on the base substrate 21, i.e., the light extraction structure 231 may also be disposed below the pixel defining layer 27, which may enhance the light extraction efficiency of the light emitted by the electroluminescent layer 252 in the obliquely downward direction. It should be noted that, in the embodiments of the present disclosure, the light extraction structure 231 in the first structural layer 23 is strip-shaped, and multiple light extraction structures 231 are arranged along a direction f2 perpendicular to the length direction of the light extraction structure 231 (as shown in FIG. 5, the embodiments of the present application are not limited to this). The “two adjacent light extraction structures 231” described above may refer to two light extraction structures 231 adjacent in the direction f2, and in this structure, the distance between any two adjacent light extraction structures 231 may be equal or unequal.

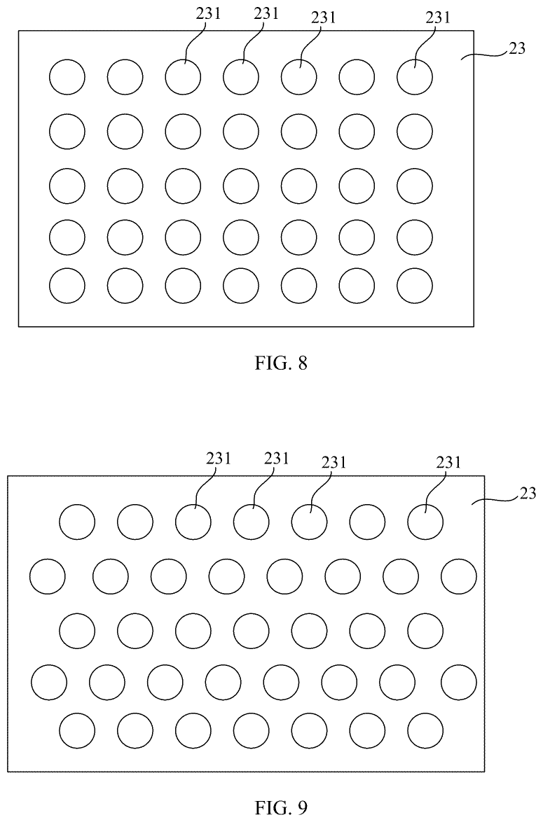

In some embodiments, referring to FIG. 8, FIG. 8 is a schematic structural diagram of a top view of another first structural layer in a display panel according to some embodiments of the present disclosure. The light extraction structures 231 in the first structural layer 23 are arranged in a row-column pattern (the “row-column pattern” means that the light extraction structures 231 are arranged in multiple rows and columns). The “two adjacent light extraction structures 231” described above refer to two adjacent light extraction structures 231 in the same row or two adjacent light extraction structures 231 in the same column. Each light extraction structure 231 may have four adjacent light extraction structures 231 at the top, bottom, left, right, and left. The distance between the light extraction structure 231 and each adjacent light extraction structure 231 may be equal or unequal, and the distances between different light extraction structures 231 and their adjacent light extraction structures 231 may also be equal or unequal.

Referring to FIG. 9, FIG. 9 is a schematic structural diagram of a top view of another first structural layer in a display panel according to some embodiments of the present disclosure. The light extraction structures 231 in the first structural layer 23 are arranged in multiple rows and two adjacent rows of the light extraction structures 231 are staggered. In such a structure, the “two adjacent light extraction structures 231” described above may refer to two adjacent in a row or two adjacent diagonally. That is, for each of the light extraction structures 231 (except for the light extraction structure 231 disposed at the edge), there are two adjacent light extraction structures 231 in the row direction and four adjacent light extraction structures 231 disposed in the diagonal upwardly direction (which may be the light extraction structure 231 disposed at the upper left, the light extraction structure 231 disposed at the lower left, the light extraction structure 231 disposed at the upper right, and the light extraction structure 231 disposed at the lower right, respectively), for a total of six adjacent light extraction structures 231. In this structure, the distance between the light extraction structures 231 and each adjacent light extraction structure 231 may be equal or unequal.

In some embodiments, referring to FIG. 4, the height difference Δh in the direction f1 perpendicular to the base substrate 21 is equal to a minimum distance s2 between the light extraction structure 231 in the first structural layer 23 and the first electrode 251. In the case that the first structural layer 23 satisfies such a condition, the influence of the first structural layer 23 on the light extraction efficiency can be enhanced, thereby improving the light extraction efficiency of the display panel. Exemplarily, the height difference Δh ranges from 0.2 micrometers to 1.5 micrometers.

It should be noted that in the case that the first structural layer 23 merely includes the protrusion structures 2311, the minimum distance between the light extraction structure 231 in the first structural layer 23 and the first electrode 251 is the distance in the direction f1 perpendicular to the base substrate 21 between the top of the protrusion structure 2311 and the first electrode 251. As shown in FIG. 7, in the case that the first structural layer 23 includes the protrusion structures 2311 and the recess structures 2312, the minimum distance is the distance in the direction f1 perpendicular to the base substrate 21 between the top of the protrusion structure 2311 and the first electrode 251. As shown in FIG. 6, in the case that the first structural layer 23 merely includes the recess structures 2312, the minimum distance is the distance in the direction perpendicular to the substrate 21 between the position between adjacent recess structures 2312 (the position farthest from the substrate 21 in the direction perpendicular to the substrate 21) and the first electrode 251.

In some embodiments, the thickness of the first structural layer 23 is equal to the thickness of the second structural layer 24. Exemplarily, the thickness of the first structural layer 23 and the thickness of the second structural layer 24 both range from 1 micron to 2 microns. For example, the thickness of the first structural layer 23 and the thickness of the second structural layer 24 may both be 1.5 microns. It should be noted that since the first structural layer 23 and the second structural layer 24 are uneven film layers, the thickness of the first structural layer 23 and the thickness of the second structural layer 24 may refer to an average thickness, e.g., the thickness of the structure may be the average of the maximum thickness and the minimum thickness of the film layer (the first structural layer 23 or the second structural layer 24), where the maximum thickness is the thickness at the protrusion structure, and the minimum thickness is the thickness in the recess structure. Alternatively, the thickness of the first structural layer 23 and the thickness of the second structural layer 24 may also refer to the maximum thickness or the minimum thickness, which is not limited by the embodiments of the present disclosure.

In some embodiments, the material of the first structural layer 23 includes an acrylic material to which a photosensitive group, a catalytic group, a surfactant, and the like are added. Alternatively, the material of the first structural layer 23 may also be other photoresist materials, which is not limited by the embodiments of the present disclosure.

The refractive index of the first structural layer 23 is lower than the refractive index of the second structural layer 24. Exemplarily, the refractive index of the first structural layer 23 is less than or equal to 1.5, for example, the refractive index of the first structural layer 23 is 1.5.

In the case that the first structural layer 23 is made of photoresist material, the protrusion structures and/or recess structures on the first structural layer 23 may be formed by an exposure development process. Alternatively, the protrusion structures and/or the recess structures are also formed by some other processes, such as a thermal reflow process and a nanoimprint process, which is not limited by the embodiments of the present disclosure.

In addition, in the first structural layer 23 in the display panel according to some embodiments of the present disclosure, the slope angel of the protrusion structure and the recess structure may range from 30 degrees to 60 degrees. This avoids excessive inclination or sharpness of the protrusion and recess structures, enhancing the positive influence of the first structural layer 23 on the light extraction efficiency and thus improving the light extraction efficiency of the overall display panel. For the case where the light extraction structure is a convex lens or a concave lens, the above slope angle range refers to the slope angle of the intermediate portion of the lens (convex or concave), where the intermediate portion refers to a portion between the top and bottom of the lens. For example, the convex or concave lens may be divided into three equal-height portions in the height direction, and the intermediate portion is the above-mentioned middle portion of the lens.

FIG. 4 illustrates a schematic diagram of the protrusion structure 2311 including a convex lens, but in the display panel provided in the embodiments of the present application, the protrusion structure 2311 may also include other types of protrusion structures. In some embodiments, the protrusion structure 2311 includes at least one of a convex lens, a triangular protrusion structure, a columnar protrusion structure, or a trapezoidal protrusion structure.

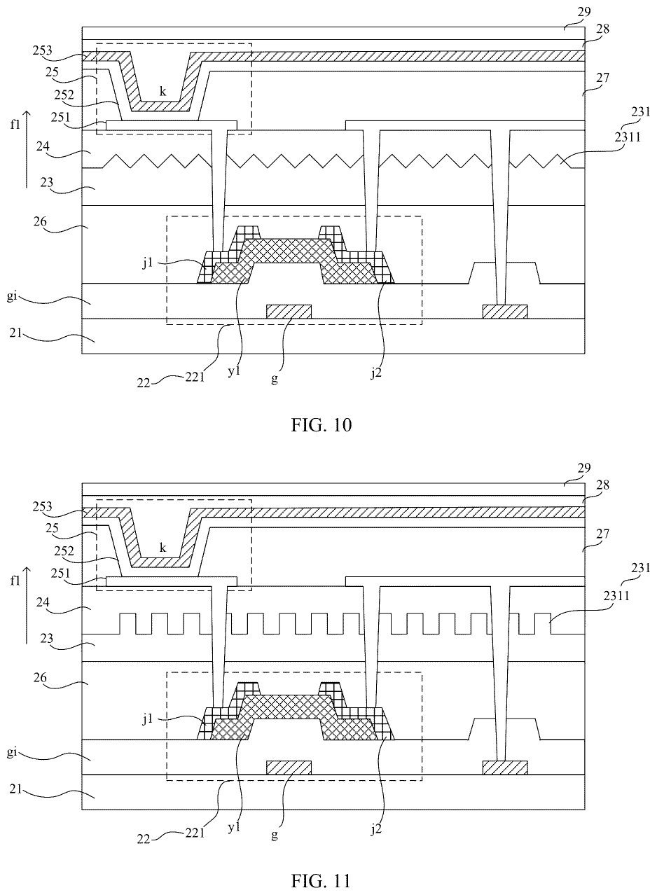

Exemplarily, FIG. 10 is a schematic structural diagram of another display panel according to some embodiments of the present disclosure. As shown in FIG. 10, the protrusion structures 2311 in the first structural layer 23 include triangular protrusion structures, and these triangular protrusion structures can also achieve the effect of improving light extraction efficiency.

In addition, the display panel further includes other structures. For example, the display panel includes a first structural layer 26, a pixel defining layer 27, a forth structural layer 28, and an packaging layer 29. The third structural layer 26 is disposed between the circuit structural layer 22 and the first structural layer 23, since the circuit structural layer 22 has a large step difference in different regions, the third structural layer 26 provides a formation surface for the upper film structure (e.g., the first structural layer 23) to enhance the positive effect of the first structural layer 23 on the light extraction efficiency. The pixel defining layer 27 is disposed between the second structural layer 24 and the electroluminescent layer 252. The pixel defining layer 27 has multiple openings k, and the electroluminescent layer 252 covers the openings k. The second electrode 253 covers the electroluminescent layer 252, such that the electroluminescent layer 252 in the openings k is in contact with the first electrode 251 and the second electrode 252. The second electrode 252 and the first electrode 251 then drive the electroluminescent layer 252 disposed in the opening of the pixel defining layer 27 to emit light. The forth structural layer 28 is disposed above the second electrode 253 for providing a formation surface to a subsequent film layer (such as the packaging layer 29). Exemplarily, the forth structural layer 28 structures the step difference caused by the openings k in the pixel defining layer 27. The packaging layer 29 is disposed on a side of the forth structural layer 28 away from the base substrate 21 for packaging the various devices in the display panel to protect them.

In some embodiments, the circuit structural layer 22 includes a thin film transistor (TFT) 221, the thin film transistor 221 includes a first pole j1, a second pole j2, and a gate g, the gate g is used to control the on-off of the first pole j1 and the second pole j2, and the first pole j1 is connected to the first electrode 251 of the light-emitting unit 25 (the first electrode 251 may be connected to the first pole j through via holes in multiple film layers between the first electrode 251 and the thin film transistor 221). In addition, the circuit structural layer 22 may also include an active layer y1 and a gate insulating layer gi. The gate g, the gate insulating layer gi, and the active layer y1 are disposed sequentially on the base substrate 21, and the first pole j1 and the second pole j2 are both in contact with the active layer y1, and the gate g is used to control the active layer y1 to realize the on-off of the first pole j1 and the second pole j2. Among them, one of the first pole j1 and the second pole j2 is the source pole and the other is the drain pole. The second pole j2 may also be connected to some other lines, and the embodiments of the present disclosure will not be repeated herein.

In some embodiments, the electroluminescent layer 252 is a white electroluminescent layer for emitting white light. The display panel further includes a color filter layer cf disposed between the first structural layer 23 and the base substrate 21, and the orthographic projection of the white electroluminescent layer 252 on the base substrate 21 overlaps with the orthographic projection of the color filter layer cf on the base substrate 21. That is, the light-emitting unit may be a white organic light-emitting diode (WOLED), which can emit white light under driving and cooperate with the color filter layer to emit various colors of light. Exemplarily, the display panel may include multiple pixels arranged in an array, and each pixel structure includes three sub-pixels. Each sub-pixel may include a light-emitting unit and a color filter layer. The three sub-pixels in the pixel may be a red sub-pixel, a blue sub-pixel, and a green sub-pixel, respectively. The red sub-pixel includes a white light-emitting unit and a red color filter layer, the blue sub-pixel may include a white light-emitting unit and a blue color filter layer, and the green sub-pixel may include a white light-emitting unit and a green color filter layer. In some embodiments, a pixel in the display panel may also include four sub-pixels, which may include the red sub-pixel, the blue sub-pixel, and the green sub-pixel as described above, and in addition, a white sub-pixel. The white sub-pixel may include only the white light-emitting unit without the color filter layer, or may include a transparent color filter layer.

In the display panel according to some embodiments of the present disclosure, the light-emitting unit may also be a red light-emitting unit, a green light-emitting unit, and a blue light-emitting unit, that is, the display panel may include multiple pixels arranged in an array, each pixel structure including three sub-pixels, the three sub-pixels in the pixel may be a red sub-pixel, a blue sub-pixel, and a green sub-pixel, respectively. The red sub-pixel may include a red light-emitting unit for emitting red light, the blue sub-pixel may include a blue light-emitting unit for emitting blue light, and the green sub-pixel may include a green light-emitting unit for emitting green light. Further, the display panel includes various color resistors. For example, the red sub-pixel may further include a red color filter layer to improve the purity of the red light emitted by the red sub-pixel, the blue sub-pixel may include a blue color filter layer to improve the purity of the blue light emitted by the blue sub-pixel, and the green sub-pixel may include a green color filter layer to improve the purity of the green light emitted by the green sub-pixel.

As shown in FIG. 11, FIG. 11 is a schematic structural diagram of another display panel according to some embodiments of the present disclosure. The protrusion structures 2311 in the first structural layer 23 include columnar protrusion structures, and these columnar protrusion structures can also improve light extraction efficiency. A top view of the columnar projection structures can be referred to in FIG. 5 (FIG. 5 illustrates a bar-shaped columnar protrusion structure), FIG. 8, or FIG. 9, which is not repeated herein. In addition, some other structures may be included in the display panel shown in FIG. 11, which may be referred to the embodiments shown in FIG. 10, and the present disclosure embodiments will not be repeated herein.

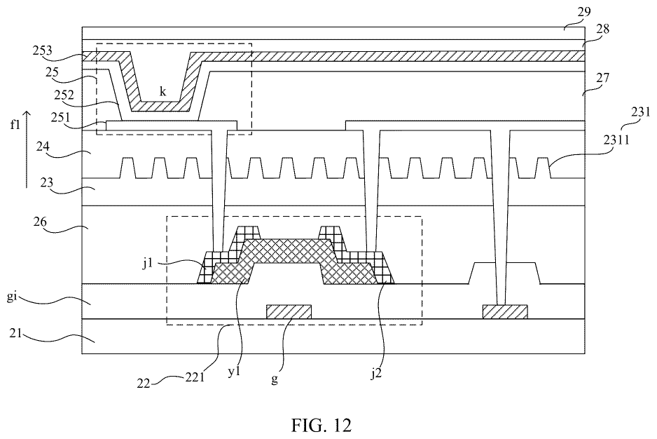

As shown in FIG. 12, FIG. 12 is a schematic structural diagram of another display panel according to some embodiments of the present disclosure. The protrusion structures 2311 in the first structural layer 23 include trapezoidal protrusion structures, and these trapezoidal protrusion structures can also improve light extraction efficiency. A top view of the trapezoidal projection structures can be referred to in FIG. 5 (FIG. 5 illustrates a bar-shaped trapezoidal projection structure), FIG. 8, or FIG. 9, which is not repeated herein. In addition, some other structures may be included in the display panel shown in FIG. 12, which may be referred to as embodiments shown in FIG. 10, and the present disclosure embodiments will not be repeated herein.

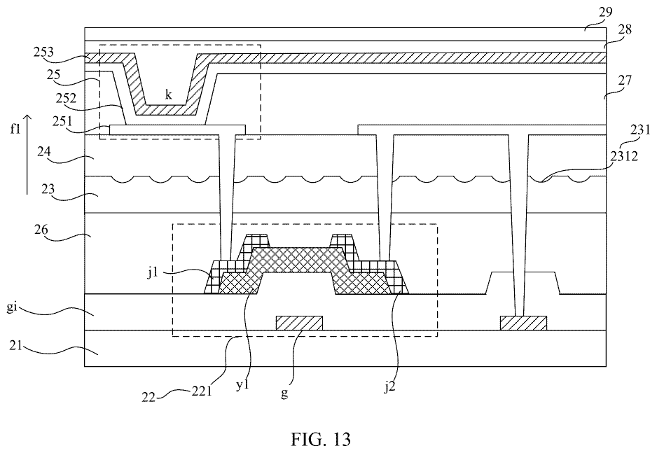

In the display panel according to some embodiments of the present disclosure, in the case that the first structural layer 23 includes a recess structure, the recess structure may have multiple structures. Exemplarily, referring to FIG. 13, FIG. 13 is a schematic structural diagram of another display panel according to some embodiments of the present disclosure. The recess structures 2312 in the first structural layer 23 include concave lenses, and these concave lenses can also improve light extraction efficiency. A top view of the concave lenses can be referred to in FIG. 5 (FIG. 5 illustrates a bar-shaped concave lens), FIG. 8, or FIG. 9, which is not repeated herein. In addition, some other structures may be included in the display panel shown in FIG. 13, which may be referred to as embodiments shown in FIG. 10, and the present disclosure embodiments will not be repeated herein.

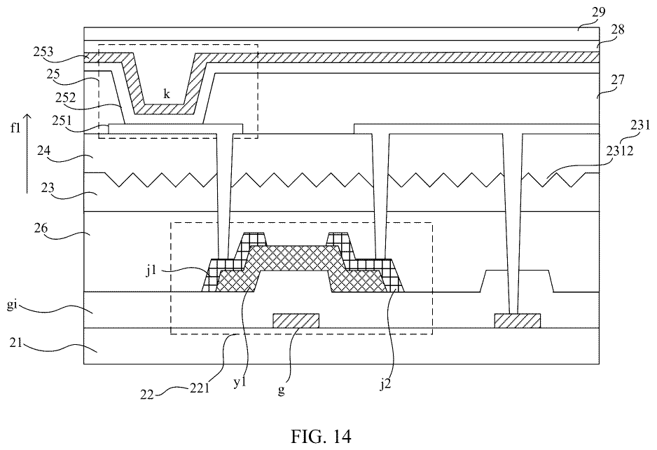

Referring to FIG. 14, FIG. 14 is a schematic structural diagram of another display panel according to some embodiments of the present disclosure. The recess structures 2312 in the first structural layer 23 include triangular recess structures, and these triangular recess structures can also improve light extraction efficiency. A top view of the triangular recess structures can be referred to in FIG. 5 (FIG. 5 illustrates a bar-shaped triangular recess structure), FIG. 8, or FIG. 9, which is not repeated herein. In addition, some other structures may be included in the display panel shown in FIG. 14, which may be referred to as embodiments shown in FIG. 10, and the present disclosure embodiments will not be repeated herein.

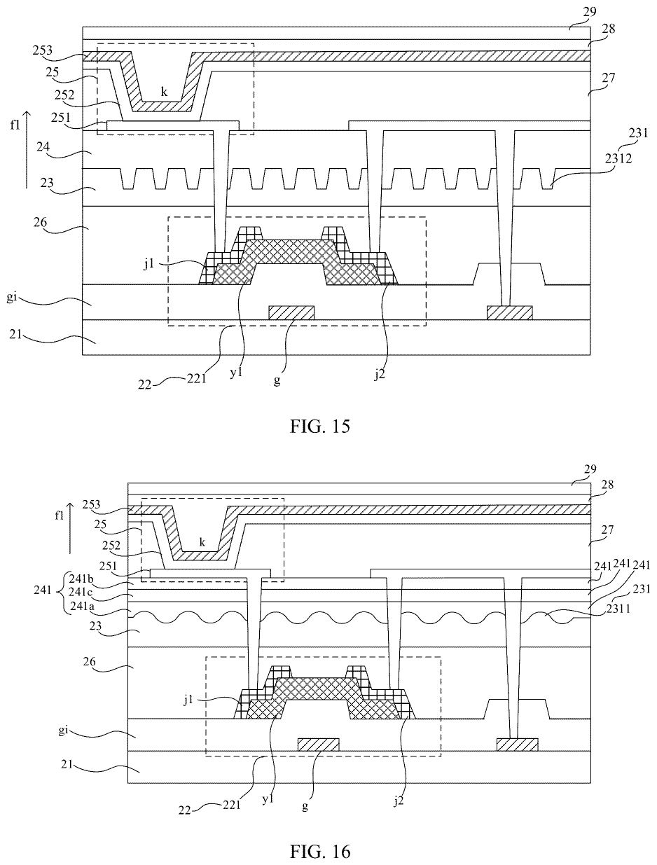

Referring to FIG. 15, FIG. 15 is a schematic structural diagram of another display panel according to some embodiments of the present disclosure. The recess structures 2312 in the first structural layer 23 include trapezoidal recess structures, and these trapezoidal recess structures can also improve light extraction efficiency. A top view of the trapezoidal recess structures can be referred to in FIG. 5 (FIG. 5 illustrates a bar-shaped trapezoidal recess structure), FIG. 8, or FIG. 9, which is not repeated herein. In addition, some other structures may be included in the display panel shown in FIG. 15, which may be referred to as embodiments shown in FIG. 10, and the present disclosure embodiments will not be repeated herein.

The above embodiments provide recess structures and protrusion structures of the multiple structures in the first structural layer 23, and at least one structure of the above plurality of structures may be included in the first structural layer 23 of the display panel provided by the embodiments of the present disclosure. Further, the surface of the second structural layer 24 facing the first structural layer 23 may have a shape complementary to the multiple light extraction structures on the first structural layer 23.

FIG. 16 is a schematic structural diagram of another display panel according to some embodiments of the present disclosure. The second structural layer 24 includes multiple sub-film layers 241 stacked in a cascade, and the refractive index of any sub-film layer 241 among multiple sub-film layers 241 is positively correlated with a first distance s1. The first distance s1 is a distance between the sub-film layer 241 and the first structural layer 23 in the direction perpendicular to the base substrate 21. That is, the refractive index of the multiple sub-film layers 241 included in the second structural layer 24 gradually increases in the direction away from the first structural layer 23. Such a structure of the second structural layer 24 further improves the light extraction efficiency for the light in the first electrode 251, thereby improving the light extraction efficiency of the overall display panel.

In some embodiments, the multiple sub-film layers 241 include a first sub-film layer 241a adjacent to the first structural layer 23 and a second sub-film layer 241b adjacent to the first electrode 251, i.e., the first sub-film layer 241a is the lowermost layer (sub-film layer closest to the base substrate 21) among the multiple sub-film layers 241, and the second sub-film layer 241b is the uppermost layer (sub-film layer furthest from the base substrate 21) among the multiple sub-film layers 241.

Therein, the refractive index of the first sub-film layer 241a is greater than the refractive index of the first structural layer 23, and the refractive index of the second sub-film layer 241b is less than or equal to the refractive index of the first electrode 251. Under such a structure, as the refractive index of the multiple sub-film layers 241 gradually increases in the direction away from the first structural layer 23, the first sub-film layer 241a is the sub-film layer with the smallest refractive index among the multiple sub-film layers 241 of the second structural layer 24, and the second sub-film layer 241b is the sub-film layer with the largest refractive index among the multiple sub-film layers 241 of the second structural layer 24. As the refractive index of the first sub-film layer 241a with the smallest refractive index among the multiple sub-film layers 241 is greater than the refractive index of the first structural layer 23, the first sub-film layer 241a can realize the screening of light directed to the first structural layer 23 from the first sub-film layer 241a to avoid light with a larger exit angle from being directed to the first structural layer 23. The refractive index of the second sub-film layer 241b with the largest refractive index among the multiple sub-film layers 241 in the second structural layer 24 has a refractive index less than or equal to the refractive index of the first electrode 251, so that the second sub-film layer 241b can also screen the light in the first electrode 251 that are directed to the second sub-film layer 241b when the refractive index of the second sub-film layer 241b is less than the refractive index of the first electrode 251 to avoid light with a larger exit angle to be directed to the second sub-film layer 241b, and the light in the first electrode 251 is convenient to be directed to the second sub-film layer 241b when the refractive index of the second sub-film layer 241b is equal to the refractive index of the first electrode 251.

In addition, based on the range of the refractive index of the first sub-film layer 241a and the range of the refractive index of the second sub-film layer 241b, a range of the refractive indices of the multiple sub-film layers 241 of the second structural layer 24 is determined, i.e., the refractive index of sub-film layers disposed between the first sub-film layer 241a and the second sub-film layer 241b may be greater than or equal to the refractive index of the first sub-film layer 241a and less than or equal to the refractive index of the second sub-film layer 241b.

In some embodiments, the multiple sub-film layers further include a third sub-film layer 241c disposed between the first sub-film layer 241a and the second sub-film layer 241b. The refractive index of the first sub-film layer 241a is greater than 1.5 and up to 1.6, a refractive index of the third sub-film layer 241c is greater than 1.6 and up to 1.7, and the refractive index of the second sub-film layer 241b is greater than 1.7 and up to 1.8. refractive index. After testing, when the refractive indices of the first sub-film layer 241a, the second sub-film layer 241b, and the third sub-film layer 241c satisfies the above refractive index ranges, the light extraction efficiency of the structure including the second structural layer 24 and the first structural layer 23 is improved, and thus the light extraction efficiency of the overall display panel is improved, thereby improving the brightness and the display effect of the display panel.

In some embodiments, more sub-film layers may be included in the second structural layer 24. Exemplarily, the multiple sub-film layers further include multiple cascading fourth sub-film layers disposed between the first sub-film layer 241a and the second sub-film layer 241b, the multiple fourth sub-film layers having refractive indices that are less than the refractive index of the second sub-film layer 241b, greater than the refractive index of the first sub-film layer 241a, and gradually increase in the direction away from the first structural layer 23.

In some embodiments, the multiple sub-film layers are formed as an integral structure. That is, the second structural layer 24 including the multiple sub-film layers is actually one membrane layer, and different thickness intervals in the membrane layer define different sub-film layers. Exemplarily, starting from a side of the second structural layer 24 close to the first structural layer, 0 micrometers to

$$\frac{1}{3} x$$

micrometers is the first sub-film layer 241a,

$$\frac{1}{3} x$$

micrometers to

$$\frac{2}{3} x$$

micrometers is the third sub-film layer 241c, and

$$\frac{2}{3} x$$

microns to X microns for the second sub-film layer 241b, x being the thickness of the second structural layer 24.

The second structural layer 24 of the one-piece structure may be formed in a single process. Exemplarily, the second structural layer 24 includes a base layer and particles doped in the base layer. The particles of different diameters may be doped in the second structural layer 24, and particles of different diameters may flow and be located at different heights in the base layer due to their different weights, thereby realizing a structure with different refractive indices of the membrane layer in different thickness intervals.

In some embodiments, the second structural layer 24 including multiple sub-film layers may also be multiple film layers formed separately, which may be formed separately by multiple processes, and the embodiments of the present disclosure do not limit this.

In some embodiments, the multiple sub-film layers 241 all include a base layer and particles doped in the base layer, and a concentration of the particles in each of the multiple sub-film layers 241 is positively correlated with the first distance s1. That is, the higher the particle concentration, the greater the refractive index of the sub-film layer 241.

Exemplarily, the second structural layer 24 includes a first sub-film layer, a third sub-film layer, a fourth sub-film layer, and a second sub-film layer stacked sequentially along the direction away from the first structural layer. Starting from the first structural layer, in the thickness direction of the second structural layer 24, from 0 to 20 nanometers is the first sub-film layer, and the concentration of particles in the first sub-film layer ranges from 10% to 20%, from 20 nanometers to 50 nanometers is the third sub-film layer, the particle concentration in the third sub-film layer ranges from 20% to 30%, 50 nanometers to 100 nanometers is the fourth sub-film layer, the particle concentration in the fourth sub-film layer ranges from 30% to 40%, 100 nanometers to 300 nanometers is the second sub-film layer, and the particle concentration in the second sub-film layer ranges from 40% to 50%. It should be noted that since the second structural layer 24 has a protrusion or recess shape complementary to the shape of the light extraction structure 231 on the first structural layer 23, the starting position of the first sub-film layer described above may refer to a position with the greatest thickness of the second structural layer 24 that is in contact with the first structural layer 23, or it may refer to a position with the least thickness.

In some embodiments, the base layer is made of a polymethyl methacrylate, a polyimide-like material, or an epoxy resin-like material. The particles include at least one of zirconium oxide and titanium oxide. In some embodiments, the material of the base layer of the second structural layer and the material of the particles may be other, and the embodiments of the present disclosure do not limit this.

In summary, according to the display panel provided by the embodiments of the present disclosure, the second structural layer is provided on the first structural layer having the light extraction structure, and the first electrode and the electroluminescent layer in the light-emitting unit are sequentially provided on the second structural layer. Since the refractive index of the second structural layer is greater than that of the first structural layer and is less than or equal to that of the first electrode, the second structural layer guides the light incident on the first electrode out of the first electrode and transmit it through the second structural layer toward the first structural layer, so that the light extraction structure on the first structural layer processes the light to improve the light extraction efficiency, which improves the uniformity of the thickness of the electroluminescent layer without decreasing the light extraction efficiency and solves the problem of poor display effect of the display panel caused by the uneven thickness of the electroluminescent layer in the related art, thereby enhancing the display effect of the display panel.

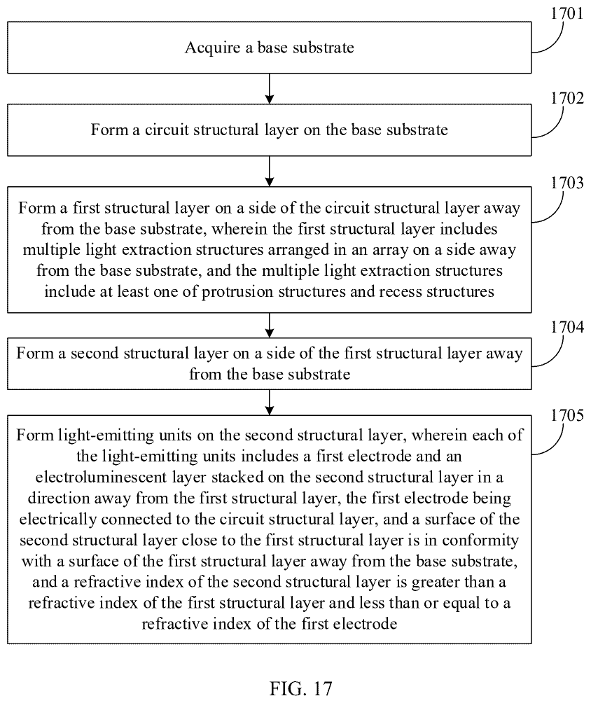

FIG. 17 is a flowchart of a method for manufacturing a display panel according to some embodiments of the present disclosure, and the method includes the following steps.

In step 1701, a base substrate is acquired.

In step 1702, a circuit structural layer is formed on the base substrate.

In step 1703, a first structural layer is formed on a side of the circuit structural layer away from the base substrate, wherein the first structural layer includes multiple light extraction structures arranged in an array on a side away from the base substrate, and the multiple light extraction structures include at least one of protrusion structures and recess structures.

In step 1704, a second structural layer is formed on a side of the first structural layer away from the base substrate.

In step 1705, light-emitting units are formed on the second structural layer, wherein each of the light-emitting units includes a first electrode and an electroluminescent layer stacked on the second structural layer in a direction away from the first structural layer, the first electrode being electrically connected to the circuit structural layer, and a surface of the second structural layer close to the first structural layer is in conformity with a surface of the first structural layer away from the base substrate, and a refractive index of the second structural layer is greater than a refractive index of the first structural layer and less than or equal to a refractive index of the first electrode.

Wherein the surface of the second structural layer close to the first structural layer is in conformity with the surface of the first structural layer away from the base substrate.

In summary, according to the method for manufacturing a display panel provided by embodiments of the present disclosure, the second structural layer is provided on the first structural layer having the light extraction structure, and the first electrode and the electroluminescent layer in the light-emitting unit are sequentially provided on the second structural layer. Since the refractive index of the second structural layer is greater than that of the first structural layer and is less than or equal to that of the first electrode, the second structural layer guides the light incident on the first electrode out of the first electrode and transmit it through the second structural layer toward the first structural layer, so that the light extraction structure on the first structural layer processes the light to improve the light extraction efficiency, which improves the uniformity of the thickness of the electroluminescent layer without decreasing the light extraction efficiency and solves the problem of poor display effect of the display panel caused by the uneven thickness of the electroluminescent layer in the related art, thereby enhancing the display effect of the display panel.

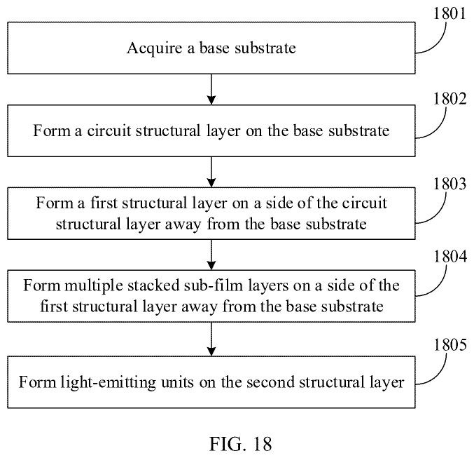

FIG. 18 is a flowchart of another method for manufacturing a display panel according to some embodiments of the present disclosure, and the method includes the following steps.

In step 1801, a base substrate is acquired.

The display panel provided by embodiments of the present disclosure may be a bottom-emission display panel, i.e., the light is emitted from the base substrate side of the display panel. In this way, the base substrate is a light-transmissive base substrate. Exemplarily, the base substrate is made of optical glass.

In step 1802, a circuit structural layer is formed on the base substrate.

The circuit structural layer may be formed on the base substrate through multiple patterning processes. The patterning process involved in the embodiments of the present disclosure may include the steps such as coating photoresist, exposure, development, etching, and stripping the photoresist.

Referring to FIG. 10, the circuit structural layer 22 includes a thin film transistor (TFT) 221, the thin film transistor 221 includes a first pole j1, a second pole j2, and a gate g, the gate g is used to control the on-off of the first pole j1 and the second pole j2, and the first pole j1 is connected to the first electrode 251 of the light-emitting unit 25 (the first electrode 251 may be connected to the first pole j through via holes in multiple film layers between the first electrode 251 and the thin film transistor 221). In addition, the circuit structural layer 22 may also include an active layer y1 and a gate insulating layer gi, the gate g, the gate insulating layer gi, and the active layer y1 are disposed sequentially on the base substrate 21, and the first pole j1 and the second pole j2 are both in contact with the active layer y1, and the gate g is used to control the active layer y1 to realize the on-off of the first pole j1 and the second pole j2. Among them, one of the first pole j1 and the second pole j2 is the source pole and the other is the drain pole. The first electrode j1 and the second electrode j2 may be of the same layer structure and formed in a single patterning process.

In step 1803, a first structural layer is formed on a side of the circuit structural layer away from the base substrate.

The first structural layer includes multiple light extraction structures arranged in an array, and the multiple light extraction structures include at least one of protrusion structures and recess structures. The light extraction structure can be referred to the above embodiments, which is not repeated herein.

In step 1804, multiple sub-film layers are formed on a side of the first structural layer away from the base substrate.

The multiple sub-film layers form the second structural layer, the refractive index of any sub-film layer among the multiple sub-film layers is positively correlated with a first distance, the first distance being a distance between the sub-film layer and the first structural layer in the direction perpendicular to the base substrate. That is, the refractive index of the multiple sub-film layers included in the second structural layer gradually increases in the direction away from the first structural layer. The second structural layer of this structure can further improve the light extraction efficiency for the light in the first electrode, thereby improving the light extraction efficiency of the overall display panel.

In some embodiments of the present disclosure, the stacked multiple sub-film layers are formed separately through multiple patterning processes, or the stacked multiple sub-film layers are formed as an integral structure, which is formed in a single process. Exemplarily, the second structural layer includes a base layer and particles doped in the base layer. The particles of different diameters may be doped in the second structural layer, and particles of different diameters may flow and be located at different heights in the base layer due to their different weights, thereby realizing a structure with different refractive indices of the membrane layer in different thickness intervals.

In step 1805, light-emitting units are formed on the second structural layer.

Each of the light-emitting units includes a first electrode and an electroluminescent layer stacked on the second structural layer in the direction away from the second structural layer.

The multiple sub-film layers in the second structural layer include a first sub-film layer adjacent to the first structural layer and a second sub-film layer adjacent to the first electrode, i.e., i.e., the first sub-film layer is the lowermost layer (sub-film layer closest to the base substrate) among the multiple sub-film layers, and the second sub-film layer is the uppermost layer (sub-film layer furthest from the base substrate) among the multiple sub-film layers.

The refractive index of the first sub-film layer is greater than the refractive index of the first structural layer, and the refractive index of the second sub-film layer is less than or equal to the refractive index of the first electrode. Under such a structure, the first sub-film layer is the sub-film layer with the smallest refractive index among the multiple sub-film layers of the second structural layer, and the second sub-film layer is the sub-film layer with the largest refractive index among the multiple sub-film layers of the second structural layer. As the refractive index of the first sub-film layer with the smallest refractive index among the multiple sub-film layers is greater than the refractive index of the first structural layer, the first sub-film layer can realize the screening of light directed to the first structural layer from the first sub-film layer to avoid light with a larger exit angle from being directed to the first structural layer. The refractive index of the second sub-film layer with the largest refractive index among the multiple sub-film layers in the second structural layer has a refractive index less than or equal to the refractive index of the first electrode, so that the second sub-film layer can also screen the light in the first electrode that is directed to the second sub-film layer when the refractive index of the second sub-film layer is less than the refractive index of the first electrode to avoid light with a larger exit angle to be directed to the second sub-film layer, and the light in the first electrode is convenient to be directed to the second sub-film layer when the refractive index of the second sub-film layer is equal to the refractive index of the first electrode.

In summary, according to the method for manufacturing a display panel provided by embodiments of the present disclosure, the second structural layer is provided on the first structural layer having the light extraction structure, and the first electrode and the electroluminescent layer in the light-emitting unit are sequentially provided on the second structural layer. Since the refractive index of the second structural layer is greater than that of the first structural layer and is less than or equal to that of the first electrode, the second structural layer guides the light incident on the first electrode out of the first electrode and transmit it through the second structural layer toward the first structural layer, so that the light extraction structure on the first structural layer processes the light to improve the light extraction efficiency, which improves the uniformity of the thickness of the electroluminescent layer without decreasing the light extraction efficiency and solves the problem of poor display effect of the display panel caused by the uneven thickness of the electroluminescent layer in the related art, thereby enhancing the display effect of the display panel.

In addition, embodiments of the present disclosure provide a display device. The display device includes a housing and any of the display panels provided in the above embodiments, the display panel being disposed in the housing.

In some embodiments, the display device also includes a power assembly and a control assembly, the power assembly is electrically connected to the display panel for providing electrical energy to the display panel. The control assembly is electrically connected to the display panel for sending control signals to the display panel and receiving feedback signals from the display panel.

The term “and/or” in the present disclosure is merely a description of an association relationship of the associated objects. “And/or” indicates that three relationships may be present. For example, A and/or B may indicate that only A is present, both A and B are present, and only B is present. The symbol “/” generally indicates an “or” relationship between the associated objects.

In the present disclosure, the term “at least one of A and B” merely describes the association relationship of the associated objects and indicates that three relationships may be present. For example, at least one of A and B may indicate that: only A is present, both A and B exist are present, and only B is present. Similarly, “at least one of A, B, and C” indicates that seven relationships may be present and may indicate that: only A is present, only B is present, only C is present, both A and B are present, both A and C are present, both C and B are present, and A, B, and C are all present. Similarly, “at least one of A, B, C, and D” indicates that fifteen relationships may be present and may indicate that: only A is present, only B is present, only C is present, only D is present, both A and B are present, both A and C are present, both A and D are present, both C and B are present, both D and B are present, both C and D are present, A, B, and C are all present, A, B, and D are all present, A, C, and D are all present, B, C, and D are all present, and A, B, C, and D are all present.

It should be noted that in the accompanying drawings, the sizes of the layers and regions may be exaggerated for clarity of illustration. Also, it should be understood that in the case that an element or layer is referred to as being “on” another element or layer, it may be directly on the other element, or an intermediate layer may be present. In addition, it should be understood that in the case that an element or layer is referred to as being “under” another element or layer, it may be directly under the other element, or one or more intermediate layers or elements may be present. In addition, it should also be understood that in the case that a layer or element is referred to as being “between” two layers or elements, it may be the only layer between the two layers or elements, or one or more intermediate layers or elements may also be present. Like reference numerals refer to like elements throughout the present disclosure.

In the embodiments disclosed herein, the terms “first”, “second”, “third” and “fourth” are used solely for descriptive purposes and should not be construed as indicating or implying relative importance. The term “a plurality of/multiple” refers to two or more, unless otherwise explicitly defined.

The foregoing descriptions are merely optional embodiments of the present disclosure and are not intended to limit the present disclosure. Any modification, equivalent replacement, and improvement within the spirit and principle of the present disclosure shall be included within the protection scope of the present disclosure.

1. A display panel, comprising:
a base substrate;
a circuit structural layer disposed on the base substrate;
a first structural layer disposed on a side of the circuit structural layer away from the base substrate, wherein the first structural layer comprises a plurality of light extraction structures arranged in an array on a side away from the base substrate, and the plurality of light extraction structures comprises at least one of protrusion structures or recess structures;
a second structural layer disposed on a side of the first structural layer away from the base substrate; and
light-emitting units disposed on the second structural layer, wherein each of the light-emitting units comprises a first electrode and an electroluminescent layer stacked on the second structural layer in a direction away from the first structural layer, the first electrode being electrically connected to the circuit structural layer, and a surface of the second structural layer close to the first structural layer is in conformity with a surface of the first structural layer away from the base substrate;
wherein a refractive index of the second structural layer is greater than a refractive index of the first structural layer and less than or equal to a refractive index of the first electrode.

2. The display panel according to claim 1, wherein the second structural layer comprises a plurality of stacked sub-film layers, and a refractive index of any sub-film layer among the plurality of sub-film layers is positively correlated with a first distance, the first distance being a distance in a direction perpendicular to the base substrate between the sub-film layer and the first structural layer.

3. The display panel according to claim 2, wherein the plurality of sub-film layers comprises a first sub-film layer adjacent to the first structural layer and a second sub-film layer adjacent to the first electrode, a refractive index of the first sub-film layer being greater than the refractive index of the first structural layer, and a refractive index of the second sub-film layer being less than or equal to the refractive index of the first electrode.

4. The display panel according to claim 3, wherein the plurality of sub-film layers further comprise a third sub-film layer disposed between the first sub-film layer and the second sub-film layer;
wherein the refractive index of the first sub-film layer is in a range (1.5, 1.6], a refractive index of the third sub-film layer is in a range (1.6, 1.7], and the refractive index of the second sub-film layer is in a range (1.7, 1.8].

5. The display panel according to claim 2, wherein the plurality of sub-film layers are formed as an integral structure.

6. The display panel according to claim 2, wherein each of the plurality of sub-film layers comprises a base layer and particles doped in the base layer, a concentration of the particles in each of the plurality of sub-film layers being positively correlated with the first distance.

7. The display panel according to claim 6, wherein the base layer is made of a polymethyl methacrylate material, a polyimide-based material, or an epoxy resin-based material.

8. The display panel according to claim 6, wherein the particles comprise at least one of zirconium oxide or titanium oxide.

9. The display panel according to claim 1, wherein a distance between centers of two adjacent light extraction structures among the plurality of light extraction structures is ½ of a height difference in the first structural layer, the height difference being a maximum distance between two positions on the first structural layer in a direction perpendicular to the base substrate.

10. The display panel according to claim 9, wherein the height difference ranges from 0.2 microns to 1.5 microns.

11. The display panel according to claim 9, wherein in the direction perpendicular to the base substrate, the height difference in the first structural layer is equal to a minimum distance between a light extraction structure in the first structural layer and the first electrode.

12. The display panel according to claim 1, further comprising: a pixel defining layer disposed between the second structural layer and the electroluminescent layer;
wherein an opening is arranged in the pixel defining layer, the electroluminescent layer covers the opening, and an orthographic projection of the pixel defining layer on the base substrate is overlapped with an orthographic projection of the plurality of light extraction structures on the base substrate.

13. The display panel according to claim 1, wherein a surface of the first electrode close to the base substrate is in conformity with a surface of the second structural layer close to the first electrode; wherein
the surface of the second structural layer close to the first electrode is flat, or
the surface of the second structural layer close to the first electrode and a surface of the first structural layer close to the second structural layer are both concave-convex.

14. The display panel according to claim 1, wherein a thickness of the first structural layer is equal to a thickness of the second structural layer.

15. The display panel according to claim 1, wherein the protrusion structures comprise at least one selected from a group consisting of a convex lens, a triangular protrusion structure, a columnar protrusion structure, and a trapezoidal protrusion structure; and
the recess structures comprise at least one selected from a group consisting of a concave lens, a triangular recess structure, a columnar recess structure, and a trapezoidal recess structure.

16. The display panel according to claim 1, wherein
the electroluminescent layer is a white electroluminescent layer for emitting white light; and
the display panel further comprises a color filter layer disposed between the first structural layer and the base substrate, an orthographic projection of the white electroluminescent layer on the base substrate being overlapped with an orthographic projection of the color filter layer on the base substrate.

17. The display panel according to claim 1, wherein the circuit structural layer comprises a thin film transistor, and the thin film transistor comprises a first pole, a second pole, and a gate, the gate being configured to control on or off of the first pole and the second pole, and the first pole being connected to the first electrode of the light-emitting unit.

18. A method for manufacturing a display panel, comprising:
acquiring a base substrate;
forming a circuit structural layer on the base substrate;
forming a first structural layer on a side of the circuit structural layer away from the base substrate, wherein the first structural layer comprises a plurality of light extraction structures arranged in an array on a side away from the base substrate, and the plurality of light extraction structures comprises at least one of protrusion structures and recess structures;
forming a second structural layer on a side of the first structural layer away from the base substrate;
forming light-emitting units on the second structural layer, wherein each of the light-emitting units comprises a first electrode and an electroluminescent layer stacked on the second structural layer in a direction away from the first structural layer, the first electrode being electrically connected to the circuit structural layer, and a surface of the second structural layer close to the first structural layer is in conformity with a surface of the first structural layer away from the base substrate, a refractive index of the second structural layer being greater than a refractive index of the first structural layer and less than or equal to a refractive index of the first electrode.

19. The method according to claim 18, wherein the second structural layer comprises a plurality of stacked sub-film layers stacked; and forming the second structural layer on the side of the first structural layer away from the base substrate comprises:
forming the plurality of stacked sub-film layers on the side of the first structural layer away from the base substrate, wherein a refractive index of any sub-film layer among the plurality of sub-film layers is positively correlated with a first distance, the first distance being a distance in a direction perpendicular to the base substrate between the sub-film layer and the first structural layer.

20. A display device, comprising a housing and a display panel, wherein the display panel is disposed in the housing; and the display panel comprises:
a base substrate;
a circuit structural layer disposed on the base substrate;
a first structural layer disposed on a side of the circuit structural layer away from the base substrate, wherein the first structural layer comprises a plurality of light extraction structures arranged in an array on a side away from the base substrate, and the plurality of light extraction structures comprises at least one of protrusion structures or recess structures;
a second structural layer disposed on a side of the first structural layer away from the base substrate; and
light-emitting units disposed on the second structural layer, wherein each of the light-emitting units comprises a first electrode and an electroluminescent layer stacked on the second structural layer in a direction away from the first structural layer, the first electrode being electrically connected to the circuit structural layer, and a surface of the second structural layer close to the first structural layer is in conformity with a surface of the first structural layer away from the base substrate;
wherein a refractive index of the second structural layer is greater than a refractive index of the first structural layer and less than or equal to a refractive index of the first electrode.
